(19) United States
(12) Patent Application Publication
(10) Pub. No.: US 2026/0247880 A1
(43) Pub. Date: Aug. 20, 2026

(54) PASSIVATION OF METAL STRUCTURES FOR HARSH ENVIRONMENTS

(71) Applicant: X-FAB GLOBAL SERVICES GMBH, Erfurt (DE)

(72) Inventors: Sophia DEMPWOLF, Erfurt (DE); Roy KNECHTEL, Geratal (DE)

(21) Appl. No.: 19/162,140

(22) PCT Filed: Mar. 8, 2024
(86) PCT No.: PCT/EP2024/056163

§ 371 Date: Sep. 4, 2025

(30) Foreign Application Priority Data
Mar. 10, 2023 (GB) 2303545.4

(51) Int. Cl. H10P 14/60; H10P 14/40; H10P 14/692; H10P 14/694; H10W 20/00; H10W 20/41; H10W 20/44; H10W 20/48

(52) U.S. Cl. CPC H10P 14/6336; H10P 14/412; H10P 14/6516; H10P 14/6682; H10P 14/6686; H10P 14/69215; H10P 14/6922; H10P 14/69433; H10W 20/067; H10W 20/081; H10W 20/435; H10W 20/4441; H10W 20/48

(57) ABSTRACT

A method of manufacturing a semiconductor structure includes providing a substrate, forming an active region in the substrate, and depositing and patterning a metal layer to form metal lines and one or more contacts connected to the active region. The method also includes depositing a silicon oxide layer by plasma enhanced chemical vapor deposition, PECVD, so as to cover at least a part of the metal layer and depositing a silicon nitride layer by low pressure chemical vapor deposition, LPCVD, so as to cover at least a part of the silicon oxide layer.

### CROSS-REFERENCE TO RELATED APPLICATIONS

This application is a national stage filing of PCT International Application No. PCT/EP2024/056163 filed on Mar. 8, 2024 (corresponding to International Publication No. WO 2024/188852), which in turn claims priority to United Kingdom Application No. GB 2303545.4 filed on Mar. 10, 2023. The entire contents of both of these applications are incorporated by reference herein.

### TECHNICAL FIELD

This disclosure relates to passivation of metal structures for harsh environments and in particular passivation in semiconductor and MEMS structures.

### BACKGROUND

The passivation of metal structures, typically aluminium-based is carried out using silicon nitride. Silicon nitride may be required in passivation systems as a moisture repellent layer and barrier. Conventionally, the nitride is deposited by using plasma enhanced chemical vapor deposition (PECVD), since the process is carried out at low temperatures and is thus compatible with the metal systems commonly used in microsystems technology to avoid diffusion and alloy formation.

### SUMMARY

Aspects of the disclosure provide a semiconductor structure and a method of forming such as set out in the appended claims.

Embodiments of the invention are described below with reference to the accompanying drawings.

### BRIEF DESCRIPTION OF DRAWINGS

FIG. 1 shows a schematic cross section of at least a part of a semiconductor structure according to an embodiment;

FIG. 2 shows a schematic cross section of at least a part of a semiconductor structure according to another embodiment comprising a noble metal;

FIG. 3 shows a schematic cross section of at least a part of a semiconductor structure according to an embodiment arranged to be used in a harsh environment; and

FIG. 4 is a flow diagram illustrating the steps of a method of forming a semiconductor structure according to an embodiment.

### DETAILED DESCRIPTION

Conventionally, a PECVD nitride coating is used as passivation layer to protect underlying metal structures from corrosion. The disadvantages of PECVD nitride coatings are:
Relatively low chemical stability.
Relatively high defect density in the layer (e.g. the layer may comprise a high density of so called “pin holes”)

In order to achieve suitable passivation properties, very thick layers are required Under extreme operating conditions (high temperatures, chemically aggressive substances, high pressures), the PECVD nitride layer can be damaged and corrosive media and ions can penetrate to the microsystem or IC, ultimately leading to system failure.

Embodiments described herein provide protection of integrated circuits and/or micromechanical structures (also referred to as MEMS structures herein) so that they can be used in aggressive/harsh environments or can be further processed by using aggressive chemicals like etchants. The protection can be provided by a high-density silicon nitride deposited by LPCVD (low pressure chemical vapor deposition), which has high chemical resistance. This is due to the strong bonds of the silicon nitride molecule structures resulting from the deposition from the gas phase at high temperatures (e.g. above 600° C.). Embodiments may be particularly suitable as sensors (e.g. pressure and/or temperature sensors) for harsh environments (e.g. in fuel, combustion engine exhaust systems or in hot oil).

LPCVD is a process for depositing layers on a substrate (typically a semiconductor substrate such as silicon). It is a chemical process running at elevated temperatures and at reduced pressure. The temperature range for LPCVD is 500° C. to 1000° C., and the pressure for an LPCVD process is in the range of 0.01 mbar to 10 mbar. The temperature during the deposition process provides the energy for the chemical reaction of two or more gasses forming the material to be deposited. The reduced pressure supports the actual deposition process on the substrate surface and prevents particle generation in the volume of the creation furnace. To deposit Silicon Nitride, Ammonia and Dichlorosilane are reacted to Silicon Nitride which is formed as a dense layer at the wafer surface. The chemical reaction depends on the actual deposition temperatures and pressure and is not always completely stoichiometric.

High temperatures (e.g. >600° C.) are conventionally considered as too high to be used to deposit an LPCVD silicon nitride at the end of the manufacturing process (wafer process) of integrated circuits or micromechanical structures. If LPCVD deposition is implemented without special additional measures, the metallization structures of the back-end-of-line, which ultimately need to be protected with regard to their application, may be destroyed by temperature related diffusion and alloying. The same applies to the contacts of the metals to the silicon structures, which can be damaged by alloy formation at high deposition temperatures and long process times.

Embodiments described herein can solve at least some of these problems by providing an industrially applicable process for depositing high-density LPCVD silicon nitride on ready-processed integrated circuits and micromechanical structures to protect them, including their metallizations, without the metals being negatively affected during the deposition of the LPCVD nitride layer. Integrated circuits and micromechanical structures protected in this way can be used safely and with long-term stability under the most extreme conditions, such as those prevailing in exhaust systems or hot media (e.g. oils).

Conventional PECVD (plasma enhanced chemical vapor deposition) silicon nitride or silicon oxide layers (and combinations thereof) deposited at temperatures below 450° C. may not be able to provide this protection due to weaker internal bonding ratios and due to layer defects (e.g., pin holes) occurring with this type of deposition. In addition, LPCVD layers can be made thinner than PECVD layers, with even better protection, which significantly reduces the mechanical stress, especially on micromechanical structures (lower thermo-mechanical stresses). Due to the thinner thickness and the characteristics of the LPCVD deposition process (batch process with parallel deposition on up to 200 wafers), more economical processing is also possible.

In addition to the improved protection for applications in aggressive operating conditions, the arrangement of layers with embedded metals can also be used as an etching mask, e.g. for etching silicon in hot potassium hydroxide (KOH) solution. The LPCVD silicon nitride layer can then provide the required protection, also for the embedded metal.

The LPCVD deposition temperature may be in the range of 500° C. to 750° C. To provide sufficiently improved protection, a deposition temperature of more than 600° C. can be used. The specific deposition temperature is determined by additional targeted layer parameters (mechanical layer stresses, residual electrical conductivity, etc.). The complete structures to be protected must withstand this deposition temperature of the LPCVD nitride layer. This applies in particular to the metallization and the contacts of these to the silicon structures. In addition, metal structures should be prevented from oxidizing when the wafers are loaded into the LPCVD system. Here, due to the process, elevated temperatures already prevail and in the presence of oxygen from the air, this can lead to the unwanted and critical oxidation of metals. The embodiments may thus comprise a special layer system, which is produced with a special process sequence in such a way that the protective LPCVD layer is produced as the last layer (top passivation layer).

Compared to a conventional PECVD nitride, an LPCVD nitride layer has a denser structure, less impurities from the formation process, and is closer to the Stoichiometric ratio of Si₃N₄, which makes it chemically more stable. The LPCVD nitride layer also has a higher thermal and mechanical stability during backend end of line (BEOL) processes and assembly processes. This allows a nitride layer deposited by LPCVD to be distinguished from a nitride layer formed by a different process (e.g. PECVD).

According to an embodiment, the method comprises the following process Sequence:
a) Use of temperature stable metal (e.g., comprising tungsten) and possibly also chemically very stable metal (e.g. comprising gold or platinum) as conductive path material and (wire) bond pads—deposition and photolithographic patterning of the metal on the integrated circuits or micromechanical structures, alternatively lift-off patterning of the metal. The metal is typically a metal layer stack comprising a first metal, an adhesion layer and a diffusion barrier layer. For example, the stable metal may be a metal layer stack comprising tungsten, titanium (Ti), and titanium nitride (TIN), wherein Ti is an adhesion layer and TiN a diffusion barrier layer. Alternatively, instead of Ti based adhesion and barrier layers, the metal layer stack may comprise tantalum (Ta) based layers, for example in combination with chromium (Cr) and nickel (Ni). In some embodiments tungsten can be replaced by aluminum (Al) or gold (Au) for example.
b) Covering of this metal by a PECVD silicon oxide layer. This deposition can be carried out at low temperatures (e.g. less than 450° C.) and completely in vacuum (e.g. at <1 Torr); there is no risk or a significantly reduced risk of oxidation of the metal, since the complete deposition process is carried out in the vacuum.
c) Densification annealing of the PECVD silicon oxide at a temperature higher than the later LPCVD nitride deposition temperature (e.g. in the range of 800 C to 1000 C). By steps b) and c) a very dense, high temperature stable silicon oxide layer is formed, which serves as an effective oxidation protection during the subsequent deposition of LPCVD nitride, especially when the wafers are loaded into the corresponding equipment. The densification can reduce the thickness of the PECVD silicon oxide layer by 10% to 40%. The PECVD layer protects the metal layer during the densification and is thick enough to prevent origin diffusion when handling the wafer in the furnace. In the furnace, a nitrogen atmosphere is used.
d) deposition of LPCVD nitride at high temperatures (e.g. above 600° C.)
e) opening of contacts or bond pads to the uppermost metal layer, whereby these contacts can also be resistant to the aggressive/harsh media or are arranged so that they are not in direct contact with the aggressive media when in use.

The overall temperature budget can be kept low, so that no significant or even critical alloy formation occurs in the electrical contacts, especially to monocrystalline and polycrystalline silicon. This means that deposition temperatures and process times can be adjusted accordingly. This is made possible in particular by the fact that even very thin PECVD oxide layers and very thin LPCVD nitride layers provide very good protection.

The PECVD oxide layer is typically a TEOS layer. TEOS Layers are Silicon oxide layers deposited using PECVD processes with TEOS Tetraethylorthosilikate, also named Tetraethoxysilan as reaction gas or precursor. The power of the plasma at medium temperature (e.g. 300° C. to 450° C.) allows the TEOS gas to transform over some interim states to SiO2, which forms a layer on the substrate. This layer is not very dense. The SiO2 tetraeters, which are forming all Silicon Oxide layers and glasses have relatively long distances to each other and are not linked at all their Oxygen atoms to the neighboring tetraeter. Between the treaters there are Hydrogen atoms and organic residue (molecule level). This makes the TEOS oxide layer in as deposited state rather unstable. With a densification bake at temperatures in the range of 800 to 1000° C., Hydrogen and organic residues are out gassed, and the SiO2 teraeters are bonded directly to each other (via the Oxygen atoms). This forms a structure nearly as dense as the one of fused silica or thermally grown oxide. This means the TEOS oxide layer can be much denser and have much better properties (chemically and mechanically). The densification process reduces the TEOS oxide layer thickness. The TEOS layer can be either doped (i.e. containing doped precursors) or undoped. In doped TEOS, Boron and/or Phosphorus is added. In other embodiments, the PECVD layer may be silane based.

Embodiments may involve structures for the protection of metal structures of integrated circuits and/or micromechanical structures against aggressive media/environments, comprising the metal structures to be protected (single or multilayer), a densified PECVD silicon oxide layer and a final LPCVD silicon nitride layer.

A semiconductor structure may be formed by deposition and structuring of high-temperature stable, possibly also chemically stable, metals by photolithographic methods or lift-off (single or multilayer). Deposition of a silicon oxide layer by PECVD methods, at low temperatures (e.g. less than 450° C.), as a process carried out completely in vacuum. The method further comprises densification of this PECVD oxide layer at temperatures higher than the subsequent LPCVD deposition temperature, preparation of this layer for subsequent higher temperatures, and LPCVD nitride deposition at temperatures higher than 600° C., to achieve a dense, protective silicon nitride layer. Further, the method may comprise opening of contacts or bond pads to the top metal layer

The process according can have a low temperature budget, by low annealing times and low layer thicknesses, to avoid critical alloy formation in contacts of the metals to mono-or polycrystalline silicon. In some applications, it may be necessary to etch the silicon e.g. to release mechanical structures by an undercutting etch with wet chemicals (e.g. in KOH or TMAH) that are very aggressive and would attack the metal. The metals may then be embedded, and the LPCVD nitride layer may be used as a masking layer for wet etching.

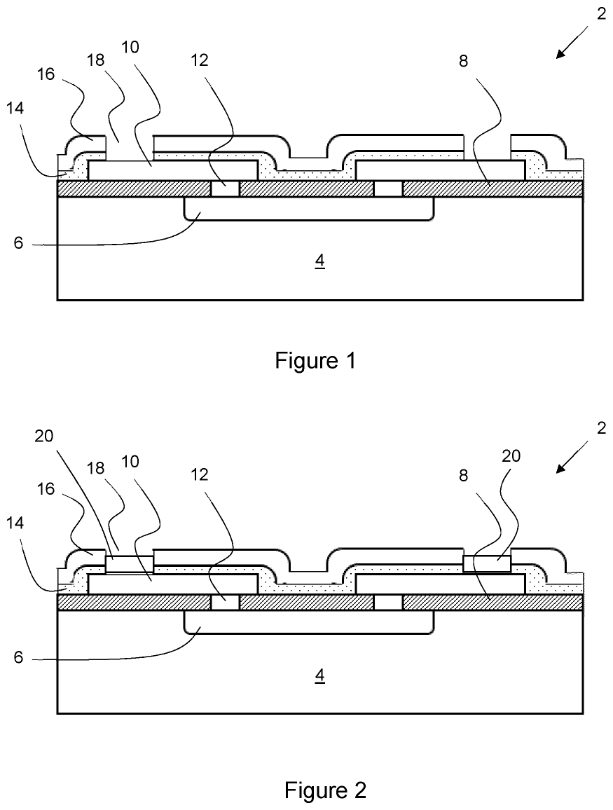

FIG. 1 shows a schematic cross section of at least a part of a semiconductor structure 2, which may be a part of a sensor for harsh environments. The structure 2 has a silicon substrate 4 with an active region 6 comprising elements of an integrated circuit or microelectromechanical system (MEMS) structure. The active region 6 typically comprises doped regions forming semiconductor devices of the integrated circuit or micromechanical structure. An intermediate insulator layer 8 is located on the substrate 4 and is arranged to electrically insulate the substrate 4 from the metal layer 10. The metal layer 10 comprises metal lines connected to the active region 6 via contacts 12. A PECVD silicon oxide layer 14 covers the metal layer 10. The passivation layer, being a LPCVD nitride layer 16, covers the oxide layer 14. Openings 18 in the PECVD oxide layer 14 and the LPCVD nitride layer 16 provide access to the metal layer 10. External wires (not shown) may be bonded directly to the metal layer 10 in the openings 18 to provide input and output signals. For example, the external wires may be soldered to the metal layer 10 or otherwise bonded so as to provide an electrical connection to the metal layer 10.

FIG. 2 shows a schematic cross section of at least a part of another semiconductor structure 2. The same reference numerals have been used in different figures for equivalent or similar features to aid understanding and are not intended to limit the illustrated embodiments. The structure 2 has a silicon substrate 4 with an active region 6 comprising elements of an integrated circuit or micromechanical structure. The active region 6 typically comprises doped regions forming semiconductor devices of the integrated circuit or micromechanical structure. An intermediate insulator layer 8 is located on the substrate 4 and is arranged to electrically insulate the substrate 4 from the metal layer 10. The metal layer 10 comprises metal lines connected to the active region 6 via contacts 12. A PECVD silicon oxide layer 14 covers the metal layer 10. The passivation layer, being a LPCVD nitride layer 16, covers the oxide layer 14. Openings 18 in the PECVD oxide layer 14 and the LPCVD nitride layer 16 provide access to the metal layer 10. A noble metal layer 20 is located in the openings 18 to provide additional protection. The noble metal layer 20 may comprise e.g. gold or platinum. For example, the noble metal layer may provide improved chemical protection and prevent oxidation or other deterioration of the metal layer 10 where the metal would otherwise be exposed by the openings 18. External wires (not shown) may be bonded to the noble metal layer 20 in the openings 18 to provide input and output signals. For example, the external wires may be soldered to the noble metal layer 20 or otherwise bonded so as to provide an electrical connection to the metal layer 20.

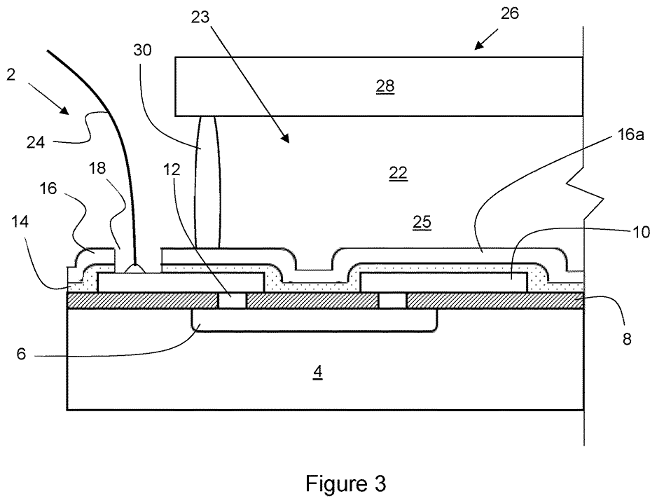

FIG. 3 shows a schematic cross section of a part of another semiconductor structure 2, such as a sensor for sensing in a harsh environment 22. The structure 2 has a silicon substrate 4 with an active region 6 comprising elements of an integrated circuit or micromechanical structure. The active region 6 typically comprises doped regions forming semiconductor devices of the integrated circuit or micromechanical structure. An intermediate insulator layer 8 is located on the substrate 4 and is arranged to electrically insulate the substrate 4 from the metal layer 10. The metal layer 10 comprises metal lines connected to the active region 6 via contacts 12. A PECVD silicon oxide layer 14 covers the metal layer 10. The passivation layer, being a LPCVD nitride layer 16, covers the oxide layer 14. Opening 18 in the PECVD oxide layer 14 and the LPCVD nitride layer 16 provides access to the metal layer 10 outside the harsh environment 22. A part 23 of the structure 2 exposed to the harsh environment 22 comprises an unbroken passivation layer 16a to fully cover the metal layer 10 in the harsh environment 22. A wire 24 is bonded to the metal layer 10 in the opening 18. The wire 24 can be arranged to provide input and/or output signals to/from the integrated circuit or micromechanical system in the active region 6. The opening 18 and wire 24 are shielded from the harsh environment by a containment structure 26 comprising a lid 28 and a seal 30 between the semiconductor structure 2 and the lid 28. For example, the harsh environment 22 may comprise hot oil 25 contained by the containment structure 26, and the semiconductor structure 2 may be a pressure sensor for measuring the pressure in the hot oil 25.

The substrate 4 may comprise multiple semiconductor layers such as a bulk silicon layer (also referred to as handling wafer), and an active layer (e.g. an epitaxial silicon layer) for forming semiconductor devices by doping.

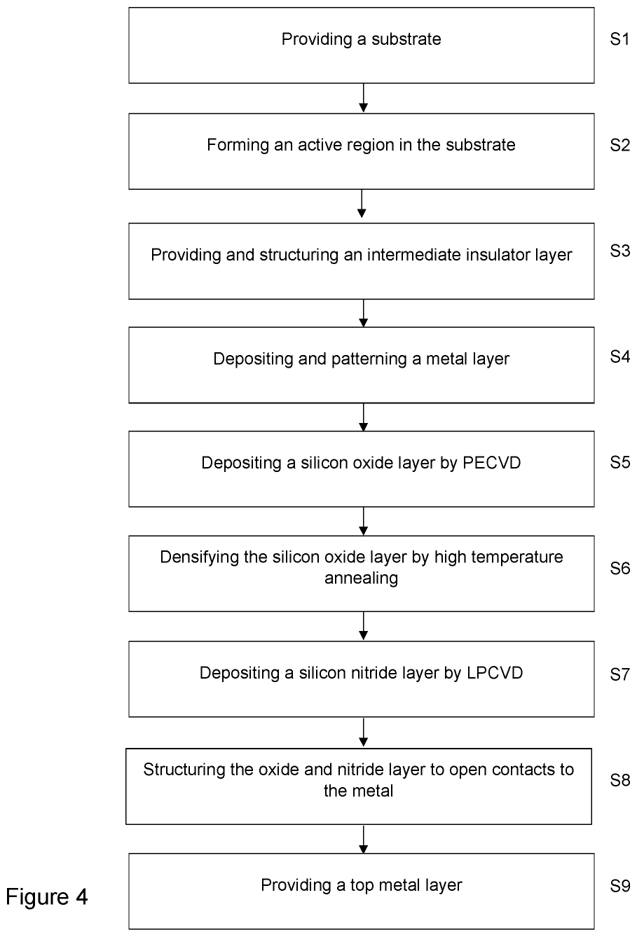

FIG. 4 shows a flow diagram of a method of forming a semiconductor structure. The method comprises providing a substrate (S1, e.g. comprising silicon), forming an active region in the substrate (S2, the active region may comprise an integrated circuit or MEMS structure), providing an insulator layer (e.g. silicon oxide) on the substrate and structuring the insulator layer to provide openings to the substrate (S3), depositing and patterning a metal layer (e.g. comprising tungsten) to form metal lines and one or more contacts connected to said active region (S4). Further layers comprising an adhesion layer and diffusion barrier layer are typically also deposited to form a metal layer stack. The method further comprises depositing a silicon oxide layer by plasma enhanced chemical vapor deposition (PECVD) on said metal layer (S5), densifying the silicon oxide layer by high temperature annealing (S6) and depositing a silicon nitride layer by low pressure chemical vapor deposition, LPCVD, on said silicon oxide layer (S7). The method further comprises structuring the oxide and nitride layers to open contacts to the metal layer (S8). Typically, the PECVD and LPCVD layers are etched to provide one or more openings to the metal layer to allow the semiconductor structure to be contacted. The method further comprises providing a second (top) metal layer for contacting the metal layer (S9).

In general, embodiments described herein may provide a semiconductor structure comprising a substrate, an active region in said substrate, a metal layer comprising metal lines and one or more contacts connected to said active region, a plasma enhanced chemical vapor deposition, PECVD, silicon oxide layer located on said metal layer, and a low pressure chemical vapor deposition, LPCVD, silicon nitride layer located on said PECVD silicon oxide layer. The semiconductor structure may be a part of a sensor, such as a pressure sensor suitable for use in harsh environments (at elevated temperatures and/or in contact with corrosive media). The structure typically comprises an insulator layer between the substrate and the metal layer, wherein the insulator layer comprises openings for the metal layer to contact said active region.

The LPCVD silicon nitride layer may be formed at a temperature at or above 600 C to improve its protective properties. For example, the LPCVD silicon nitride layer may be formed at a temperature in the range of 600 C to 750 C.

The LPCVD silicon nitride layer can have a thickness in the range of about 0.1 μm to 1 μm. The LPCVD silicon nitride layer can have a thickness less than 0.5 μm. The relatively thinness of the passivation layer allows for a lower thermal budget, which can protect the structure from deterioration (e.g. due to diffusion or alloying) during manufacturing.

The PECVD silicon oxide layer can have a thickness in the range of about 0.2 μm to 2 μm. The PECVD silicon oxide layer can have a thickness less than 1 μm.

Again, the relative thinness allows for a reduced thermal budget. The initially deposited oxide layer may have a greater thickness, which is reduced in a subsequent process step of densification annealing. The PECVD silicon oxide layer may be a TEOS layer, for example a densified TEOS layer. The TEOS layer can be doped or undoped. Alternatively, the PECVD silicon oxide layer may be a silane based oxide layer. Typically, the PECVD layer is formed directly on the metal layer, but in other embodiments there may be an intermediate layer.

The active region may comprises at least a part of a microelectromechanical system, MEMS, structure, wherein said metal layer provides an input and an output to said MEMS structure. For example, the MEMS structure may be a part of a sensor, such as a pressure sensor for use in harsh environments. Pressure signals may be output from the semiconductor structure. For example, the active region may be formed by doping and/or patterning the silicon substrate.

The active region may comprise at least a part of an integrated circuit, IC, wherein said metal layer provides an input and an output to said IC. The active region may comprise semiconductor devices such as transistors formed in the active region and connected to the metal layer.

Typically, the metal layer is made from a durable metal suitable for harsh environments. For example, the metal layer may comprise tungsten. The metal layer may be part of a metal layer stack further comprising an adhesion layer (e.g. Ti) and a diffusion barrier layer (e.g. TiN).

Said PECVD silicon oxide layer and said LPCVD silicon nitride layer may comprise one or more openings for forming electrical connections to the metal layer. For example, the LPCVD layer may cover at least 90% of a surface area of said metal layer. The structure may comprise a noble metal layer (e.g. comprising gold or platinum) on the metal layer in the openings, which may further protect the metal layer in regions where the passivation layer is removed. Thick metallization may provide connections to the metal layer via the openings in the PECVD and LPCVD layers.

Other embodiments provide a sensor (e.g. a pressure and/or temperature sensor) comprising the semiconductor structure described above.

Further embodiments provide a method of manufacturing a semiconductor structure. The method comprises providing a substrate, forming an active region in said substrate (e.g. by doping and/or patterning the substrate), and depositing and patterning a metal layer to form metal lines and one or more contacts connected to said active region. The method further comprises depositing a silicon oxide layer by plasma enhanced chemical vapor deposition, PECVD, on said metal layer, which can be followed by a densification bake, and depositing a silicon nitride layer by low pressure chemical vapor deposition, LPCVD, on said silicon oxide layer. The method may also comprise, before depositing the metal layer, depositing an insulator layer on the substrate and structuring the insulator layer to provide openings for the metal layer to contact the active region.

The step of depositing a silicon oxide layer may comprise depositing at a temperature below 450 C. The low deposition temperature helps prevent oxidation of the metal layer and other deterioration of the structure.

The deposition can be performed in a vacuum to prevent contamination or oxidation. For example, the step of PECVD depositing a silicon oxide layer may comprise depositing at a pressure of less than 1 Torr. Deposition may be followed by densification. For example, the method may comprise densification annealing of said silicon oxide layer before depositing said silicon nitride layer. The densification increase the density of the PECVD silicon oxide layer and reduces the thickness. The densification annealing may comprise annealing at a temperature above the subsequent LPCVD deposition temperature, e.g. in the range of 800 C to 1000 C.

The step of depositing said silicon nitride layer may comprise depositing at a temperature greater than 600 C. For example, the step of depositing said silicon nitride layer comprises depositing at a temperature in the range of 600 C to 750 C. The deposition may be carried out at a pressure in the range of 0.01 mbar to 10 mbar.

Optionally, the step of depositing said PECVD silicon oxide layer comprises depositing with Tetraethylorthosilikate (TEOS), with or without a doped precursor. A TEOS layer may benefit in particular from densification. Alternatively, the step of depositing said PECVD silicon oxide layer may comprise depositing with silane.

While specific embodiments have been described above, it will be apparent to one skilled in the art that modifications may be made to the embodiments as described without departing from the scope of the claims set out below. Each feature disclosed or illustrated in the present specification may be incorporated in the embodiments, whether alone or in any appropriate combination with any other feature disclosed or illustrated herein.

What is claimed is:

1. A method of manufacturing a semiconductor structure comprising:
providing a substrate;
forming an active region in said substrate;
depositing and patterning a metal layer to form metal lines and one or more contacts connected to said active region;
depositing a silicon oxide layer by plasma enhanced chemical vapor deposition, PECVD, so as to cover at least a part of said metal layer;
densification annealing of said silicon oxide layer; and
after said densification annealing, depositing a silicon nitride layer by low pressure chemical vapor deposition, LPCVD, so as to cover at least a part of said silicon oxide layer.

2. A method according to claim 1, wherein said step of depositing a silicon oxide layer comprises depositing at a temperature below 450 C.

3. A method according to claim 1, wherein said step of depositing a silicon oxide layer comprises depositing at a pressure of less than 1 Torr.

4. (canceled)

5. A method according to claim 1, wherein said step of densification annealing reduces a thickness of said PECVD silicon oxide layer by 10% to 40%.

6. A method according to claim 1, wherein said step of densification annealing comprises annealing at a temperature in the range of 800 C to 1000 C.

7. A method according to claim 1, wherein said step of depositing said silicon nitride layer comprises depositing at a temperature

8. A method according to claim 1, wherein said step of depositing said silicon nitride layer comprises depositing at a temperature in the range of 600 C to 750 C.

9. A method according to claim 1, wherein said step of depositing said silicon nitride layer comprises depositing at a pressure in the range of 0.01 mbar to 10 mbar.

10. A method according to claim 1, wherein said step of depositing said PECVD silicon oxide layer comprises depositing with Tetraethylorthosilikate (TEOS).

11. A method according to claim 1, wherein said step of depositing said PECVD silicon oxide layer comprises depositing with silane.

12. A method according to claim 1, further comprising depositing an insulator layer on said substrate and structuring said insulator layer to provide openings for said metal layer to contact said active region.

13. A semiconductor structure comprising:
a substrate;
an active region in said substrate;
a metal layer comprising metal lines and one or more contacts connected to said active region;
a plasma enhanced chemical vapor deposition, PECVD, silicon oxide layer covering at least a part of said metal layer, wherein said PECVD silicon oxide layer is a densified oxide layer; and
a low pressure chemical vapor deposition, LPCVD, silicon nitride layer covering at least a part of said PECVD silicon oxide layer.

14. A semiconductor structure according to claim 13, wherein said LPCVD silicon nitride layer was formed at a temperature at or above 600 C.

15. (canceled)

16. A semiconductor structure according to claim 13, wherein said LPCVD silicon nitride layer has a thickness in the range of 0.1 to 1 μ

17. A semiconductor structure according to any one claim 13, wherein said PECVD silicon oxide layer has a thickness in the range of 0.2 to 2 μm.

18. (canceled)

19. (canceled)

20. (canceled)

21. A semiconductor structure according to claim 13, wherein said active region comprises at least a part of a microelectromechanical system, MEMS, structure or an integrated circuit, IC, and wherein said metal layer provides an input and an output to said MEMS structure or IC.

22. A semiconductor structure according to claim 13, wherein said metal layer comprises tungsten.

23. A semiconductor structure according to claim 13, wherein said PECVD silicon oxide layer and said LPCVD silicon nitride layer comprise one or more openings for forming electrical connections to the metal layer.

24. A semiconductor structure according to claim 13, further comprising an insulator layer between said substrate and said metal layer, wherein said insulator layer comprises openings for said metal layer to contact said active region.

25. A sensor comprising a semiconductor structure according to claim 13.
